(19) United States
(12) Patent Application Publication
(10) Pub. No.: US 2019/0267557 A1
(43) Pub. Date: Aug. 29, 2019

(54) DISPLAY SUBSTRATE AND MANUFACTURING METHOD THEREOF, DISPLAY DEVICE

(71) Applicants: BOE TECHNOLOGY GROUP CO., LTD., Beijing (CN); CHENGDU BOE OPTOELECTRONICS TECHNOLOGY CO., LTD., Chengdu (CN)

(72) Inventors: Pan ZHAO, Beijing (CN); Zhiliang JIANG, Beijing (CN); Zi QIAO, Beijing (CN)

(21) Appl. No.: 16/229,935

(22) Filed: Dec. 21, 2018

(30) Foreign Application Priority Data
Feb. 28, 2018 (CN) 201810166555.1

(51) Int. Cl. H01L 51/00; H01L 27/32; H01L 51/52; H01L 51/56; G03F 7/00

(52) U.S. Cl. CPC H01L 51/0097; H01L 27/3246; H01L 2251/5338; H01L 51/56; G03F 7/0007; H01L 51/5253

(57) ABSTRACT

A display substrate and manufacturing method thereof, and a display device is provided. The display substrate includes a base substrate and at least one convex-concave structure and an inorganic layer sequentially disposed on the base substrate. The base substrate includes a display region and a non-display region located around the display region, the at least one convex-concave structure is located in the non-display region, and an orthographic projection of the at least one convex-concave structure on the base substrate is within an orthographic projection of the inorganic layer on the base substrate.

The present disclosure claims priority of the Chinese patent application No. 201810166555.1, filed on Feb. 28, 2018, the disclosure of which is incorporated herein by reference as part of the present disclosure.

### TECHNICAL FIELD

At least one embodiment of the present disclosure relates to a display substrate and a manufacturing method thereof, and a display device.

### BACKGROUND

With a popularization of electronic display products, users have higher requirements for the quality reliability of the electronic display products. For example, an organic light emitting diode (OLED) is an organic thin film electroluminescent member, which has received great attention because of having advantages such as simple preparation process, low cost, low power consumption, high brightness, wide viewing angle, high contrast, flexible display and the like. However, in a process of production or application of the electronic display products, a crack may occur in an internal component of the electronic display products. If the crack is extended, the important component may be damaged, thereby affecting product yield and increasing production cost.

### SUMMARY

At least one embodiment of the present disclosure provides a display substrate. The display substrate comprises a base substrate and at least one convex-concave structure and an inorganic layer sequentially disposed on the base substrate. The base substrate comprises a display region and a non-display region located around the display region, the at least one convex-concave structure is located in the non-display region, and an orthographic projection of the at least one convex-concave structure on the base substrate is within an orthographic projection of the inorganic layer on the base substrate.

For example, the display substrate provided by at least one embodiment of the present disclosure further comprises a barrier, and the barrier is located in the non-display region and on a side of the inorganic layer away from the base substrate.

For example, in the display substrate provided by at least one embodiment of the present disclosure, the orthographic projection of the at least one convex-concave structure on the base substrate is within an orthographic projection of the barrier on the base substrate.

For example, in the display substrate provided by at least one embodiment of the present disclosure, the base substrate comprises an organic material, the at least one convex-concave structure is a protrusion contacting the base substrate.

For example, in the display substrate provided by at least one embodiment of the present disclosure, the protrusion is integrally formed with the base substrate.

For example, in the display substrate provided by at least one embodiment of the present disclosure, the base substrate comprises an organic material, and the at least one convex-concave structure is a recess, and a portion of the base substrate facing the inorganic layer is configured to be the recess.

For example, in the display substrate provided by at least one embodiment of the present disclosure, the orthographic projection of the convex-concave structure on the base substrate is a closed loop and surrounds the display region.

For example, in the display substrate provided by at least one embodiment of the present disclosure, the at least one convex-concave structure comprises a plurality of convex-concave structures spaced from each other from inside to outside of the display region.

For example, in the display substrate provided by at least one embodiment of the present disclosure, a cross section of the at least one convex-concave structure in a direction perpendicular to an extension direction of the at least one convex-concave structure is at least one of an arc, a sector, a rectangle and a trapezoid.

For example, the display substrate provided by at least one embodiment of the present disclosure further comprises an inorganic encapsulation layer located on a side of the barrier away from the base substrate, and an orthographic projection of the barrier on the base substrate is within an orthographic projection of the inorganic encapsulation layer on the base substrate.

For example, the display substrate provided by at least one embodiment of the present disclosure further comprises a pixel defining layer located in the display region, and the pixel defining layer and at least a portion of the barrier are formed in a same layer and by a same material.

For example, in the display substrate provided by at least one embodiment of the present disclosure, the inorganic layer comprises at least one of a buffer layer, a gate insulating layer, an interlayer dielectric layer and a passivation layer.

For example, the display substrate provided by at least one embodiment of the present disclosure further comprises a transition layer located between the inorganic layer and the at least one convex-concave structure, the transition layer comprises an inorganic material, and the orthographic projection of the at least one convex-concave structure on the base substrate is located within an orthographic projection of the transition layer on the base substrate.

For example, in the display substrate provided by at least one embodiment of the present disclosure, the base substrate comprises a first material layer and a second material layer laminated with the first material layer, the second material layer is located between the first material layer and the transition layer, the first material layer is an organic material layer, and the second material layer comprises an inorganic material and an organic material.

For example, in the display substrate provided by at least one embodiment of the present disclosure, the transition layer comprises an organic material, a content of the inorganic material is greater than a content of the organic material in the transition layer, and a content of the organic material is greater than a content of the inorganic material in the second material layer.

At least one embodiment of the present disclosure provides a display device, and the display device comprises the display substrate according to any one of the above embodiments.

At least one embodiment of the present disclosure provides a manufacturing method of a display substrate, comprising: providing a base substrate, the base substrate comprising a display region and a non-display region located around the display region; forming at least one convex-concave structure on the base substrate, the at least one convex-concave structure being in the non-display region; and forming an inorganic layer on the base substrate on which the at least one convex-concave structure is formed, wherein an orthographic projection of the at least one convex-concave structure on the base substrate is within an orthographic projection of the inorganic layer on the base substrate.

For example, the manufacturing method of a display substrate provided by at least one embodiment of the present disclosure, further comprising: forming a barrier in the non-display region on the inorganic layer.

For example, in the manufacturing method of a display substrate provided by at least one embodiment of the present disclosure, the orthographic projection of the at least one convex-concave structure on the base substrate is within an orthographic projection of the barrier on the base substrate.

For example, in the manufacturing method of a display substrate provided by at least one embodiment of the present disclosure, the forming the at least one convex-concave structure comprises: patterning a surface of the base substrate, so that a portion of the surface of the base substrate facing the inorganic layer is formed to be the at least one convex-concave structure.

### BRIEF DESCRIPTION OF THE DRAWINGS

In order to demonstrate clearly technical solutions of the embodiments of the present disclosure, the accompanying drawings in relevant embodiments of the present disclosure will be introduced briefly. It is apparent that the drawings may only relate to some embodiments of the disclosure and not intended to limit the present disclosure.

FIG. 1 is a plan view of a display substrate according to an embodiment of the present disclosure;

FIG. 2 is a cross-sectional view of the display substrate of FIG. 1 taken along line A-B;

FIG. 3 is another cross-sectional view of the display substrate of FIG. 1 taken along line A-B;

FIG. 4 is a partial cross-sectional view of another display substrate according to an embodiment of the present disclosure;

FIG. 5 is a partial cross-sectional view of another display substrate according to an embodiment of the present disclosure; and

FIG. 6A to FIG. 6D are process diagrams of a manufacturing method of a display substrate according to an embodiment of the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is apparent that the described embodiments are just a part but not all of the embodiments of the disclosure. Based on the described embodiments herein, those skilled in the art can obtain other embodiment, without any creative work, which shall be within the scope of the disclosure.

Unless otherwise defined, all the technical and scientific terms used herein have the same meanings as commonly understood by one of ordinary skill in the art to which the present disclosure belongs. The terms, such as “first,” “second,” or the like, which are used in the description and the claims of the present disclosure, are not intended to indicate any sequence, amount or importance, but for distinguishing various components. The terms, such as “comprise/comprising,” “include/including,” or the like are intended to specify that the elements or the objects stated before these terms encompass the elements or the objects and equivalents thereof listed after these terms, but not preclude other elements or objects. The terms, such as “connect/connecting/connected,” “couple/coupling/coupled” or the like, are not limited to a physical connection or mechanical connection, but may include an electrical connection/coupling, directly or indirectly. The terms, “on,” “under,” “left,” “right,” or the like are only used to indicate relative position relationship, and when the position of the object which is described is changed, the relative position relationship may be changed accordingly.

Some structures such as film layers in a display substrate are composed of an inorganic material, and the film layer composed of the inorganic material has high density and may play the spacing, insulating and packaging functions and the like. However, the film layer composed of the inorganic material is generally inferior in flexibility, and the film layer is prone to be cracked under an action of external force. For example, a display substrate (or an electronic display product comprising the display substrate) may be affected by factors such as a cutting process, transportation, bending and the like during a process of production and application, and correspondingly, a crack is easily generated in the film layers composed of the inorganic material in an edge region and the like of the display substrate. If the crack extends into inside of the display substrate, important elements of the display substrate may be damaged, and external substance such as water, oxygen and the like may invade into inside of the display substrate, thereby affecting product yield and increasing production cost.

At least one embodiment of the present disclosure provides a display substrate. The display substrate comprises a base substrate and at least one convex-concave structure and an inorganic layer. The base substrate comprises a display region and a non-display region located around the display region, the inorganic layer is disposed on the base substrate, and the at least one convex-concave structure is located in the non-display region and between the base substrate and the inorganic layer, wherein an orthographic projection of the at least one convex-concave structure on the base substrate is within an orthographic projection of the inorganic layer on the base substrate. For example, in at least one embodiment of the present disclosure, the display substrate further includes a barrier, the barrier is located within the non-display region and on a side of the inorganic layer away from the base substrate. It should be noted that, in at least one embodiment of the present disclosure, the at least one convex-concave structure may comprise one convex-concave structure, and may also comprise a plurality of convex-concave structures. In the display substrate, in a case where a crack is generated in the inorganic layer between the barrier and the base substrate, if the crack extends to a region where the convex-concave structure is located, an extension direction of the crack may change due to the function of the convex-concave structure, so that the crack will not extend further or an extension speed of the crack may be slow down; in addition, in the region where the convex-concave structure is located, the convex-concave structure increases the surface area of the inorganic layer, which is equivalent to increase the extension path of the crack. Therefore, the convex-concave structure can block the crack from extending from the non-display region to the display region, thereby preventing damage to structures in the display region and improving the yield of the display substrate.

In at least one embodiment of the present disclosure, the structure of the convex-concave structure is not limited as long as the convex-concave structure may cause a surface of the inorganic layer facing the base substrate not to be in a same plane. In this way, the convex-concave structure can increase a surface area of the surface of the inorganic layer facing the base substrate, so as to increase the extension path of the crack in the inorganic layer and change the extension direction of the crack extends in the region where the convex-concave structure is located.

Hereinafter, a display substrate and a method manufacturing thereof, and a display device according to at least one embodiment of the present disclosure will be described with reference to the accompanying drawings.

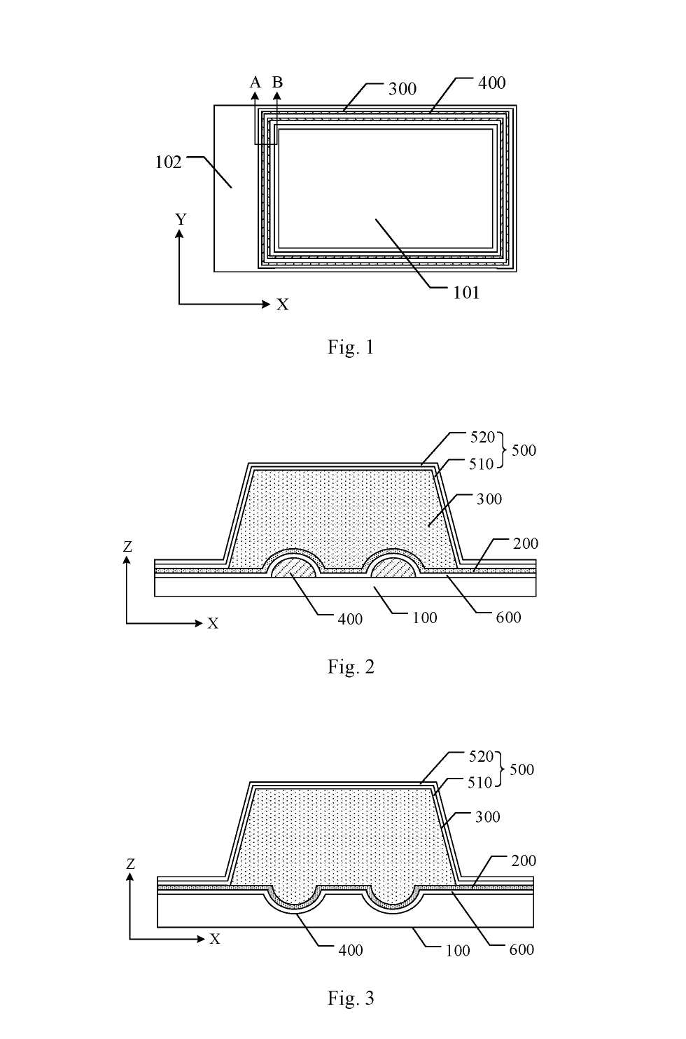

FIG. 1 is a plan view of a display substrate according to an embodiment of the present disclosure; FIG. 2 is a cross-sectional view of the display substrate of FIG. 1 taken along line A-B; and FIG. 3 is another cross-sectional view of the display substrate of FIG. 1 taken along line A-B.

As shown in FIG. 1, FIG. 2 and FIG. 3, a display substrate provided by at least one embodiment of the present disclosure comprises a base substrate 100 and an inorganic layer 200 and at least one convex-concave structure 400 disposed on the base substrate 100. The base substrate 100 comprises a display region 101 and a non-display region 102 located around the display region 101. The convex-concave structure 400 is located in the non-display region 102 and located between the base substrate 100 and the inorganic layer 200, and an orthographic projection of the at least one convex-concave structure 400 on the base substrate 100 is within an orthographic projection of the inorganic layer 200 on the base substrate 100. Since the inorganic layer 200 covers the convex-concave structure 400, in a region where the convex-concave structure 400 is located, the inorganic layer 200 is conformally formed on the convex-concave structure 400. Therefore, in the region where the convex-concave structure 400 is located, the convex-concave structure 400 increases a surface area of the inorganic layer 200, which is equivalent to increase the extension path of the crack; and when the crack extends to the region, the crack needs to change its extension direction to further extend, and the extension speed of the crack will slow or even stop, that is, the convex-concave structure 400 can slow or prevent further extension of the crack.

For example, in at least one embodiment of the present disclosure, the conformal may denote that surface shapes of two adjacent structures are the same or similar. Illustratively, as shown in FIG. 2 and FIG. 3, in a direction perpendicular to a plane in which the base substrate 100 is located, and in a case where a cross-sectional shape of a surface of the convex-concave structure 400 is an arc (the cross-sectional shape of the convex-concave structure 400 is a sector), the cross-sectional shape of the surface of a portion of the inorganic layer 200 (or a transition layer 600 in the following embodiments) that overlaps the convex-concave structure 400 is also an arc.

It should be noted that, in at least one embodiment of the present disclosure, the specific shape of the convex-concave structure is not limited as long as the convex-concave structure can increase the surface area of the inorganic layer and can have an effect of changing the extension direction of the crack. For example, in at least one embodiment of the present disclosure, at least one convex-concave structure may be a protrusion or a recess or a combination of a protrusion and a recess. For example, in some embodiments of the present disclosure, as shown in FIG. 2, the convex-concave structure 400 is a protrusion. For example, in other embodiments of the present disclosure, as shown in FIG. 3, the convex-concave structure 400 is a recess. For example, in at least one embodiment of the present disclosure, the convex-concave structure may also be a combination of a protrusions and a recess.

Hereinafter, in a case where it is not explicitly explained, the technical solution in at least one embodiment of the present disclosure will be described by taking the convex-concave structure 400 which is configured to be a protrusion shown in FIG. 2 as an example.

In at least one embodiment of the present disclosure, as shown in FIG. 1 and FIG. 2, a spatial coordinate system is established with reference to a surface on which the base substrate 100 is located, so as to directionally describe a position of each structure in the display substrate. For example, in the spatial coordinate system, directions of the X-axis and the Y-axis are parallel to a plane on which the base substrate 100 is located, and direction of the Z-axis is perpendicular to the plane on which the base substrate 100 is located. In addition, “above” and “below” are distinguished by a distance from the base substrate 100, “above” is a position close to the base substrate 100, and “below” is a position away from the base substrate 100. Illustratively, taking the inorganic layer 200 shown in FIG. 2 as an example, the protrusion 400 is located below the inorganic layer 200; the inorganic layer 200 is located above the protrusion 400; a surface of the inorganic layer 200 near the base substrate 100 is a lower surface of the inorganic layer 200; and a surface of the inorganic layer 200 away from the base substrate 100 is a upper surface of the inorganic layer 200.

For example, in at least one embodiment of the present disclosure, the orthographic projection of the convex-concave structure on the base substrate is a closed loop and distributed around the display region. Illustratively, as shown in FIG. 1, the protrusions 400 are annularly distributed around the display region 101. As such, the effect of the protrusion 400 blocking the crack from extending toward the display region 101 can be enhanced. It should be noted that, in at least one embodiment of the present disclosure, the distributing manner of the convex-concave structure on the base substrate is not limited. For example, a planar shape of the convex-concave structure may comprise a non-closed ring shape, a line segment shape and the like, as long as the distribution of the convex-concave structure can block the crack from extending to the display region.

For example, in at least one embodiment of the present disclosure, the at least one convex-concave structure comprises a plurality of convex-concave structures spaced from inside to outside of the display region. Illustratively, as shown in FIG. 1 and FIG. 2, a plurality of protrusions 400 are disposed on the base substrate 100, the plurality of protrusions 400 are spaced apart from each other, and in a plane parallel to the X-axis and the Y-axis, the protrusions 400 are arranged in sequence around the display region 101. As such, the protrusions 400 can act as multiple layers of protection for the display region 101, and further reducing a risk of the crack extending to the display region 101.

For example, in the display substrate provided by at least one embodiment of the present disclosure, a cross section of the at least one convex-concave structure taken along a direction perpendicular to an extending direction thereof comprises at least one of an arc, a sector, a rectangle, and a trapezoid. Illustratively, as shown in FIG. 2, the shape of the cross section of the protrusion 400 may be a sector, for example, may further be a semicircular. The cross-sectional shape of the convex-concave structure may be designed according to actual process requirements, which is not limited in at least one embodiment of the present disclosure, as long as the convex-concave structure has an effect of changing the extension direction of the crack.

In at least one embodiment of the present disclosure, a material of the base substrate in the display substrate is not limited. For example, in a display substrate provided by some embodiments of the present disclosure, the base substrate comprises an organic material, and the at least one of the convex-concave structures is a protrusion contacting the base substrate. For example, in a display substrate provided by other embodiments of the present disclosure, the base substrate comprises an organic material, the at least one of the convex-concave structures is a recess, and the recess is located on a side of the base substrate facing the inorganic layer. The flexibility of the organic material is high, so that the base substrate has a certain flexibility, and the display substrate can be used in a field of flexible display. Accordingly, the flexible display substrate is subjected to a large degree of bending during actual application process, which result in a higher probability of occurrence of the crack in the inorganic layer and an increased risk of further extension of the crack. Illustratively, as shown in FIG. 2, the base substrate 100 and the protrusion 400 are in direct contact, such that for the inorganic material layer (comprising the inorganic layer 200) overlying the protrusion 400, when the crack occur in the inorganic material layer, the protrusion 400 can block further extension of the crack. For example, a material of the flexible base substrate may comprise an organic resin-based material such as a polyimide-based material, a polyethylene terephthalate (PET), a polymethyl methacrylate (PMMA) and the like.

It should be noted that, in at least one embodiment of the present disclosure, a type of the base substrate in the display substrate is not limited. For example, the base substrate in the display substrate may also be a rigid substrate. For example, a material of the rigid substrate may comprise at least one of a glass material, a metal, a resin material and the like, and the resin material may comprise at least one of a polyethylene terephthalate (PET), a polymethyl methacrylate (PMMA) and the like.

Hereinafter, the technical solution in at least one embodiment of the present disclosure will be described by taking that the base substrate in the display substrate is a flexible base substrate and the material of the base substrate comprises an organic material as an example.

In at least one embodiment of the present disclosure, as shown in FIG. 2, the protrusion 400 and the base substrate 100 may be a non-integrated structure. Illustratively, in a process of manufacturing the display substrate, after the base substrate 100 is provided, a material layer may be formed on the base substrate 100, and then the material layer is patterned to form the protrusion 400.

For example, in a display substrate provided by at least one embodiment of the present disclosure, at least one convex-concave structure is integrally formed with the base substrate, that is, the convex-concave structure and the base substrate are an integrated structure. For example, when the convex-concave structure is a protrusion, the protrusion is integrally formed with the base substrate; or, when the convex-concave structure is a recess, a portion of a surface of the base substrate facing the inorganic layer may be configured as the recess. Hereinafter, the convex-concave structure will be described by taking a protrusion as an example. In a case where the protrusion and the base substrate are integrally formed, separation between the protrusion and the base substrate can be avoided, and the yield of the display substrate can be improved.

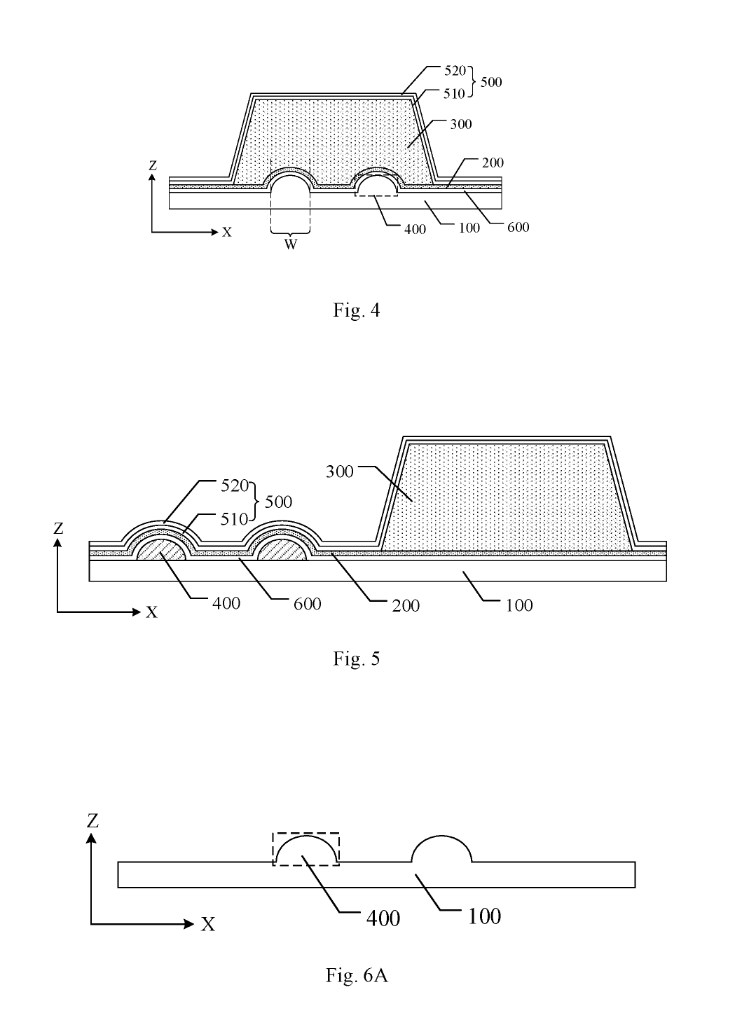

FIG. 4 is a partial cross-sectional view of another display substrate according to an embodiment of the present disclosure. Illustratively, as shown in FIG. 4, the protrusion 400 and the base substrate 100 may be integrally formed, that is, the protrusion 400 and the base substrate 100 may be obtained from a same material layer. Illustratively, in a manufacturing process of the display substrate, a material layer may be provided, and then an imprinting template is used to form the protrusion 400 on a surface of the material layer by an imprint process, and the base substrate 100 is simultaneously obtained; or, the material layer is subjected to a patterning process (for example, a wet etching, a dry etching or the like), and a portion of a surface of the material layer is formed to be the protrusion 400, and the base substrate 100 is simultaneously obtained. Compared with the display substrate shown in FIG. 2, the base substrate 100 and the protrusion 400 in the display substrate shown in FIG. 4 will not be separated, and the risk of the protrusion 400 and the inorganic layer 200 and the like being detached from the base substrate 100 is lowered, and the yield of the display substrate is improved.

In at least one embodiment of the present disclosure, a barrier may also be comprised in the display substrate, and the barrier is located within the non-display region and on a side of the inorganic layer away from the base substrate. Illustratively, as shown in FIG. 2, FIG. 3, and FIG. 4, the barrier 300 is located in the non-display region 102 and located on a side of the inorganic layer 200 away from the base substrate 100. The barrier 300 can increase an intrusion path of foreign substance such as water and oxygen, thereby protecting the internal components of the display substrate. Taking the inorganic encapsulation layer 500 in the following embodiments as an example, as shown in FIG. 2, FIG. 3 and FIG. 4, the barrier 300 increases an area of a lower surface of the inorganic encapsulation layer 500 and increases the path of water and oxygen and the like of invading the inside of the display substrate along the lower surface of the inorganic encapsulation layer 500 and reduces the risk of water, oxygen and the like entering the inside of the display substrate, thereby protecting elements (for example, an organic light emitting member) inside the display substrate.

In a manufacturing process of the display substrate, the barrier may also be used to store a material to prevent the material from overflowing, thereby improving the yield of the display substrate. For example, the display substrate is an organic light emitting diode display substrate, and an organic light emitting layer of the organic light emitting member may be manufactured by a process of inkjet printing. The barrier can prevent the corresponding inkjet printing material from overflowing, which can reduce material waste and increase a thickness of the organic light emitting layer, so that the organic light emitting member has a good light emitting function. In addition, in a packaging process of the display substrate, in a case of manufacturing an organic package layer by inkjet printing, the barrier can prevent the corresponding inkjet printing material from overflowing, thereby increasing the thickness and the uniformity of the organic package layer.

In at least one embodiment of the present disclosure, relative positions of the convex-concave structure and the barrier are not limited in a direction parallel to a plane on which the base substrate is located. For example, in at least one embodiment of the present disclosure, an orthographic projection of the at least one convex-concave structure on the base substrate is within an orthographic projection of the barrier on the base substrate.

Illustratively, the convex-concave structure is a protrusion. As shown in FIG. 2 and FIG. 4, an orthographic projection of the protrusion 400 on the base substrate 100 is located within an orthographic projection of the barrier 300 on the base substrate 100. As such, the protrusion 400 may increase a height of the barrier 300 (a distance from a surface of the barrier 300 away from the base substrate 100 to the base substrate 100), or in a case where a design height of the barrier 300 is constant, the usage amount of the material for forming the barrier 300 can be reduced. An upper surface of the inorganic layer 200 is in contact with the barrier 300, and the inorganic layer 200 and the barrier 300 have a certain bonding force, and a cooperation between the bonding force and the protrusion 400 can reduce the risk of an occurrence of the crack in the inorganic layer 200 located on the protrusion 400, or further prevent an extension of the crack. At a position where the protrusion 400 is disposed, the inorganic layer 200 may have a problem of stress accumulation due to shape deformation, and in a case where materials of the barrier 300 and the protrusion 400 are materials having a certain elasticity (for example, organic material), the barrier 300 and the protrusion 400 may facilitate uniform release of stress in the inorganic layer 200, thereby further reducing the risk of an occurrence of the crack in the inorganic layer or preventing an extension of the crack. In addition, the protrusion 400 increases a surface area of the inorganic layer 200, accordingly, in a case where the size of the barrier 300 is fixed, a contact area of the barrier 300 with the inorganic layer 200 is correspondingly increased, the adhesion of the barrier 300 to the inorganic layer 200 is increased, and the barrier 300 can be prevented from falling off.

For example, a description is provided by taking a convex-concave structure as a recess. Illustratively, as shown in FIG. 3, an orthographic projection of the recess 400 on the base substrate 100 is within an orthographic projection of the barrier 300 on the base substrate 100. An upper surface of the inorganic layer 200 is in contact with the barrier 300, and the inorganic layer 200 and the barrier 300 and the inorganic layer 200 have a certain bonding force, and the cooperation between the bonding force and the recess 400 can reduce the risk of an occurrence of the crack in the inorganic layer 200 located on the recess 400, or further prevent an extension of the crack. At a position where the recess 400 is disposed, the inorganic layer 200 may have a problem of stress accumulation due to shape deformation, and in a case where materials of the barrier 300 and the base substrate 100 are materials having a certain elasticity (for example, organic material), the barrier 300 and the recess 400 may facilitate uniform release of stress in the inorganic layer 200, thereby further reducing the risk of an occurrence of the crack in the inorganic layer or preventing an extension of the crack. In addition, the recess 400 increases a surface area of the inorganic layer 200, accordingly, in a case where the size of the barrier 300 is fixed, a contact area of the barrier 300 with the inorganic layer 200 is correspondingly increased, the adhesion of the barrier 300 to the inorganic layer 200 is increased, and the barrier 300 can be prevented from falling off.

In at least one embodiment of the present disclosure, parameters such as a thicknesses and a widths of the convex-concave structure and the barrier are not limited. For example, as shown in FIG. 4, the thickness of the protrusion 400 (a distance from an end of the protrusion 400 away from the base substrate 100 to an end of the protrusion 400 near the base substrate 100) may be 0 to 1.5 μm, for example, may further be 0.5 μm, 1 μm, 1.2 μm or the like; the width of the protrusion 400 (for example, a width W shown in FIG. 4) may be 10-20 μm, for example, may further be 12 μm, 15 μm, 18 μm or the like. For example, the thickness of the barrier 300 (a distance from an end of the barrier 300 away from the base substrate 100 to an end of the barrier 300 near the base substrate 100) may be 1.5 to 3 μm, and the barrier 300 may have a width of 40 to 50 μm. For example, in at least one embodiment of the present disclosure, in a case where the convex-concave structure is a recess, parameters such as a depth and a width of the recess may refer to the numerical range of the thickness and the width of the protrusion, which will not be described herein.

For example, in at least one embodiment of the present disclosure, an orthographic projection of the at least one convex-concave structure on the base substrate is outside an orthographic projection of the barrier on the base substrate. FIG. 5 is a partial cross-sectional view of another display substrate according to an embodiment of the present disclosure. Illustratively, as shown in FIG. 5, the orthographic projection of the protrusion 400 on the base substrate 100 is outside the orthographic projection of the barrier 300 on the base substrate 100. As such, the protrusion 400 can prevent not only an extension of the crack in the inorganic layer 200 but also an extension of a crack in other inorganic thin films (for example, the inorganic encapsulation layer 500 described in FIG. 5 and the following embodiments) provided on the display substrate. For example, the protrusion 400 may be located on a side of the barrier 300 closer to the display region 101, or the protrusion 400 may be located on a side of the barrier 300 away from the display region 101. For example, a plurality of protrusions may be disposed in the display substrate, and orthographic projections of some of the plurality of protrusions, on the base substrate are located within an orthographic projection of the barrier on the base substrate, and orthographic projections of the other of the plurality of protrusions on the base substrate are located outside the orthographic projection of the barrier on the base substrate.

In at least one embodiment of the present disclosure, a method of disposing the barrier is not limited. For example, in a process of manufacturing the display substrate, the barrier may be formed separately, or the barrier may be simultaneously manufactured in a process of manufacturing other structures of the display substrate.

For example, the display substrate provided by at least one embodiment of the present disclosure may further comprise a pixel defining layer located within the display region. For example, at least a portion of the barrier and the pixel defining layer may be formed in a same layer and by a same material. The pixel defining layer may define a plurality of pixel openings, to form an organic light emitting member in each of the pixel openings. For example, an organic light emitting layer of an organic light emitting member may be formed in the pixel opening by inkjet printing, thus, the process of manufacturing the display substrate can be simplified and the cost can be reduced.

For example, a material of the pixel defining layer may comprise polyimides, polyethylene terephthalate (PET), polymethyl methacrylate (PMMA), and the like. For example, the material of the pixel defining layer may comprise a photoresist material (for example, a photoresist), and further, a material of a spacer layer is a polyimide doped with a photoresist material. As such, in a process of manufacturing the spacer layer by a patterning process, the process of manufacturing the spacer layer is simplified and the cost is reduced. For example, the pixel defining layer may be a single layer structure or a double layer or a multilayer composite structure. For example, the pixel defining layer is a double layer structure, and the pixel defining layer comprises a first defining layer and a second defining layer sequentially stacked on the base substrate. The first defining layer is configured to be lyophilic with respect to an ink of the inkjet printing, and the second defining layer is configured to be lyophobic with respect to the ink of the inkjet printing, such that in the process of inkjet printing, the ink is bound in the pixel opening, thereby improving the function of the light emitting member and the yield of the display substrate.

For example, in at least one embodiment of the present disclosure, a spacer layer may also be disposed in the display substrate. For example, at least a portion of the barrier and the spacer layer are formed in a same layer and by a same material. For example, the barrier comprises a first film layer and a second film layer sequentially stacked on the base substrate, and the first film layer and the pixel defining layer may be formed in a same layer and by a same material, and the second film layer and the spacer layer may be formed in a same layer and by a same material. As such, a thickness of the spacer can be increased, thereby the path of water, oxygen, and the like invading to inside of the display substrate can be increased, and the water, the oxygen and the like can be prevented from invading the inside of the display substrate. The spacer layer can be used to support the display substrate or an overall thickness of a display panel comprising the display substrate, so as to avoid problems such as thickness unevenness caused by external force. For example, a cover plate may be disposed on the display substrate to form a display panel, the cover plate may protect the display substrate, and the spacer layer may be used to support the cover plate and the display substrate to maintain the thickness of the display panel.

For example, a material of the spacer layer may comprise polyimides, polyethylene terephthalate (PET), polymethyl methacrylate (PMMA), and the like. For example, the material of the spacer layer may comprise a photoresist material (for example, a photoresist), and further, the material of the spacer layer is a polyimide doped with a photoresist material. As such, in a process of manufacturing the spacer layer by a patterning process, the process of manufacturing the spacer layer is simplified and the cost is reduced.

In at least one embodiment of the present disclosure, the type of the inorganic layer between the convex-concave structure and the barrier is related to the specific structure of the display substrate, which is not limited herein. For example, in the display substrate provided by at least one embodiment of the present disclosure, the inorganic layer comprises at least one of a buffer layer, a gate insulating layer, an interlayer dielectric layer and a passivation layer. For example, the material of the above inorganic layer may comprise a silicon nitride, a silicon oxide, a silicon oxynitride, or the like.

In the display substrate provided by at least one embodiment of the present disclosure, the material of the base substrate is mainly an organic material, which can make the base substrate more flexible, so that the display substrate may be used for flexible display. Since properties of the organic material and the inorganic material are different, it is not easy to crystallize between the organic material and the inorganic material, such that bonding strength between the inorganic layer and the base substrate is low and the inorganic layer and the base substrate are easily separated. Therefore, in an actual process, a transition material may be disposed between the inorganic layer and the base substrate, and the transition material may have a large bonding strength with the inorganic material and the organic material to prevent the inorganic layer from separating from the base substrate.

For example, the display substrate provided by at least one embodiment of the present disclosure further comprises a transition layer located between the inorganic layer and the convex-concave structure, the transition layer comprises an inorganic material, and an orthographic projection of the convex-concave structure on the base substrate is within an orthographic projection of the transition layer on the base substrate. Illustratively, as shown in FIG. 2 to FIG. 5, the display substrate comprises the transition layer 600 disposed between the base substrate 100 and the inorganic layer 200. For example, the transition layer 600 may comprise an inorganic material. For example, the transition layer 600 may comprise a composite material comprising an organic material and an inorganic material. As such, the transition layer 600 and the base substrate 100, and the transition layer 600 and the inorganic layer 200 have a strong bonding force. For example, an orthographic projection of the protrusion 400 on the base substrate 100 is within an orthographic projection of the transition layer 600 on the base substrate 100. As such, the protrusions 400 can prevent an extension of the crack in the transition layer 600.

It should be noted that in at least one embodiment of the present disclosure, the base substrate may also be designed to be a composite layer (a laminated layer) comprising a plurality of film layers. For example, the base substrate may comprise a first material layer and a second material layer laminated with the first material layer, and the second material layer is located between the first material layer and the transition layer (or the convex-concave structure). For example, the first material layer is an organic material layer, and the second material layer is a composite material layer comprising an inorganic material and an organic material. For example, in the second material layer, a content of the organic material is greater than a content of the inorganic material. For example, in the transition layer, a content of the inorganic material is greater than a content of the organic material. Therefore, the bonding strengths between the transition layer and the inorganic layer, and the transition layer and the base substrate are relatively high, such that a degree of firmness of the inorganic layer fixed on the base substrate can be further improved. For example, in the base substrate and the transition layer, the inorganic material may comprise a silicon nitride, a silicon oxide, a silicon oxynitride, and the like, and the organic material may comprise a resin-based material such as polyimide and the like.

For example, the display substrate provided by at least one embodiment of the present disclosure further comprises an inorganic encapsulation layer located on a side of the barrier away from the base substrate, and an orthographic projection of the barrier on the base substrate is within an orthographic projection of the inorganic encapsulation layer on the base substrate. Illustratively, as shown in FIG. 2 to FIG. 5, the display substrate may comprise an inorganic encapsulation layer 500 disposed on a side of the barrier 300 away from the base substrate 100. The material of the inorganic encapsulating layer 500 is high in density, so that the inorganic encapsulating layer 500 can cover the surface of the display substrate to prevent water, oxygen, or the like from intruding into the inside of the display substrate. The inorganic encapsulating layer 500 covers the barrier 300, so that the harrier 300 increases an area of the lower surface of the inorganic encapsulating layer 500, that is, the path of water, oxygen, and the like invading the inside of the display substrate can be increased, and the water, the oxygen and the like can further be prevented from invading the inside of the display substrate. For example, the inorganic encapsulation layer 500 may be formed by a process such as chemical vapor deposition (CVD) or the like.

For example, the inorganic encapsulation layer 500 may be a composite layer comprising a laminated layer of at least two film layers. For example, the inorganic encapsulation layer 500 may comprise a first inorganic encapsulation layer 510 and a second inorganic encapsulation layer 520. An organic encapsulation layer may also be disposed between the first inorganic encapsulation layer 510 and the second inorganic encapsulation layer 520, and the organic encapsulation layer is mainly located in the display region. The organic encapsulation layer can planarize a surface of the display substrate and has a certain flexibility to have a buffering effect. For example, a material such as a desiccant or the like may be provided in the organic encapsulating layer, and the material may absorb intrusive elements such as water, oxygen and the like to protect components disposed inside the display substrate.

At least one embodiment of the present disclosure provides a display device comprising the display substrate according to any one of the above embodiments. For example, the display device may be an organic light emitting diode display panel, and the display substrate may serve as an array substrate in the display panel.

For example, in one example of the present disclosure, a plurality of organic light emitting members which can emit light of different colors (for example, red, green, blue and the like) may be formed in an array substrate of a display device to display an image. For example, after the array substrate is packaged, a surface on a light exit side of the array substrate may be planarized, and then the display device is obtained, therefore, other structures (such as a touch panel or the like) may be easily formed on the array substrate; or a package cover plate may also be disposed on the light exit side of the array substrate, the package cover plate and the array substrate may be bonded together by an optical adhesive, and the package cover plate has a certain strength such that the array substrate may be protected.

For example, in another example of the present disclosure, the organic light emitting member in the array substrate emits white light or a monochromatic short-wavelength light such as blue light or the like. For example, a color filter substrate may be disposed in the display device, and the color filter substrate and the array substrate are cell-assembled, thereby a color display can be realized. For example, different types of quantum dots may be disposed in a color film layer of the color filter substrate, and the quantum dots can emit different colors of light after being excited by the monochromatic short-wavelength light, such that the color display can also be realized. The quantum dots have good scattering effect on light such that a viewing angle of the display image of the display device can be increased.

For example, the display device provided by at least one embodiment of the present disclosure may be any product or component having a display function, such as a tablet computer, a television set, a display, a notebook computer, a digital photo frame, a navigator, and the like, which is not limited by at least one embodiment of the present disclosure.

At least one embodiment of the present disclosure provides a manufacturing method of a display substrate, comprising: providing a base substrate, the base substrate comprising a display region and a non-display region located around the display region; forming at least one convex-concave structure on the base substrate, the at least one convex-concave structure being located in the non-display region; and forming an inorganic layer on the base substrate on which the at least one convex-concave structure is formed, wherein an orthographic projection of the at least one convex-concave structure on the base substrate is within an orthographic projection of the inorganic layer on the base substrate. For example, the manufacturing method of the display substrate provided by at least one embodiment of the present disclosure further comprises forming a barrier on the inorganic layer, the barrier is located in the non-display region. In the display substrate obtained by the above manufacturing method, a crack may be generated in the inorganic layer between the barrier and the base substrate, if the crack extends to a region where the convex-concave structure is located, an extension direction of the crack may change, thus, the crack will not extend further or an extension speed of the crack may be slow down; in addition, in the region where the convex-concave structure is located, the convex-concave structure increases a surface area of the inorganic layer, which is equivalent to increase the extension path of the crack. Therefore, the convex-concave structure can block the crack from extending from the non-display region to the display region, thereby preventing damage to the structures in the display region and improving the yield of the display substrate.

For example, in the manufacturing method provided by at least one embodiment of the present disclosure, an orthographic projection of the at least one convex-concave structure on the base substrate is within an orthographic projection of the barrier on the base substrate. As such, in a case where the convex-concave structure is a protrusion, a height of the barrier can be increased or the usage amount of the material forming the barrier can be decreased; in addition, a bonding force between the inorganic layer and the barrier can block an extension of the crack in the inorganic layer. And in a case where the barrier and the convex-concave structure (for example, the protrusion) are materials having a certain elasticity, the stress in the inorganic layer can be uniformly and advantageously released, thereby further blocking an extension of the crack in the inorganic layer; furthermore, a contact area between the inorganic layer and the barrier is increased such that the bonding force between the barrier and the inorganic layer is increased.

For example, in the manufacturing method of a display substrate provided by at least one embodiment of the present disclosure, the forming the at least one convex-concave structure comprises: patterning a surface of the base substrate such that a portion of the surface of the base substrate facing the inorganic layer is formed to be the at least one convex-concave structure. As such, in a case where the convex-concave structure is a protrusion, separation between the protrusion and the base substrate can be avoided, and the yield of the display substrate can be improved.

It should be noted that the specific structure of the display substrate obtained by the above manufacturing method can refer to the related description in the embodiments above-mentioned, which is not described in the embodiments of the present disclosure herein.

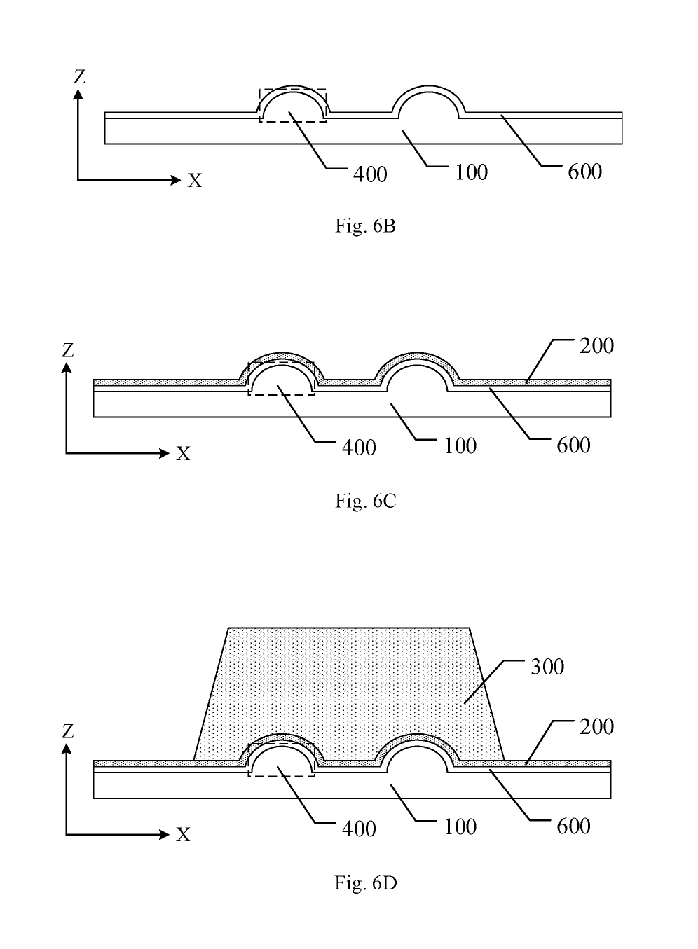

Hereinafter, in at least one embodiment of the present disclosure, a manufacturing method of a display substrate will be described. FIG. 6A to FIG. 6D are process diagrams of a manufacturing method of a display substrate according to an embodiment of the present disclosure. For example, by taking manufacturing the display substrate shown in FIG. 4 as an example, as shown in FIG. 6A to FIG. 6D, the method manufacturing of the display substrate provided by at least one embodiment of the present disclosure may comprise the following process.

As shown in FIG. 6A, a material layer is provided, and a surface of the material layer is imprinted by an imprint template to form a protrusion 400, then the material layer is cured. As such, an integrated structure of a base substrate 100 and a protrusion 400 is obtained. In addition, the surface portion of the material layer may be patterned, so that a portion of a surface of may be formed to be the protrusion 400, and the other portion of the material layer is used as the base substrate 100. The specific structure and distribution of the protrusion 400 may be referred to the relevant content in the embodiments above-mentioned, which is not described in the embodiments of the present disclosure herein.

For example, in at least one embodiment of the present disclosure, the patterning process may be a photolithographic patterning process, for example, comprise: coating a photoresist layer on a structure layer to be patterned, exposing the photoresist layer using a mask, developing the exposed photoresist layer to obtain a photoresist pattern, etching the structural layer by using the photoresist pattern, and optionally removing the photoresist pattern. It should be noted that, if the structural layer to be patterned comprises a photoresist material, the process of coating the photoresist layer may not be required.

For example, in at least one embodiment of the present disclosure, the material layer may be formed to be the base substrate 100 shown in FIG. 3 by an imprint template or a patterning process, and a recess 400 is formed on a upper surface of the base substrate 100. The specific method of forming the recess may refer to the specific process of forming the protrusion in the embodiments above-mentioned, which will not be described herein.

As shown in FIG. 6B, a material layer comprising an inorganic material is deposited on the base substrate 100 on which the protrusion 400 is formed, to form the transition layer 600. A material for manufacturing the transition layer may also comprise an organic material or the like. The material composition and distribution of the transition layer 600 may be referred to the relevant content in the embodiments above-mentioned, which is not described in the embodiments of the present disclosure herein.

As shown in FIG. 6C, an inorganic layer 200 is formed on the base substrate 100. The inorganic layer 200 may be a composite layer. For example, the inorganic layer 200 comprises a buffer layer, a gate insulating layer, an interlayer dielectric layer, a passivation layer and the like, and a manufacturing method of the inorganic layer 200 may be designed according to the manufacturing process of the thin film transistor, which is not described in the embodiments of the present disclosure herein.

As shown in FIG. 6D, an insulating material film is deposited on the base substrate 100 on which the inorganic layer 200 is formed, then the insulating material film is patterned to form a barrier 300. The barrier 300 is formed in a non-display region of the display substrate. For example, the barrier 300 and the pixel defining layer are formed in a same layer and by a same material, after the insulating material film is deposited on the base substrate 100, a patterning process is performed on the insulating material film. A portion of the insulating material film located in the display region is formed to be a pixel defining layer, and a portion of the insulating material film located in the non-display region is formed to be the barrier 300.

As shown in FIG. 4, an inorganic material film is deposited on the base substrate 100 by chemical vapor deposition, to form an inorganic encapsulation layer 500. For example, the inorganic encapsulation layer 500 may cover a surface of the display substrate. The specific structure and distribution of the inorganic encapsulation layer 500 may be referred to the relevant content in the embodiments above-mentioned, which is not described in the embodiments of the present disclosure herein.

The embodiments of the present disclosure provide a display substrate and manufacturing method thereof, and a display device, and may have at least one of the following advantageous effects:

(1) In the display substrate provided by at least one embodiment of the present disclosure, the convex-concave structure increases a surface area of the inorganic layer, which is equivalent to increase the extension path of the crack, and in a region where the convex-concave structure is located, an extension direction of the crack may be changed, thus, the crack will not extend further or an extension speed of the crack may be slow down.

(2) In the display substrate provided by at least one embodiment of the present disclosure, an orthographic projection of the at least one convex-concave structure on the base substrate is within an orthographic projection of the barrier on the base substrate, such that in a case where the convex-concave structure is a protrusion, the height of the barrier can be increased or the usage amount of the material forming the barrier can be decreased; in addition, a bonding force between the inorganic layer and the barrier can block an extension of the crack in the inorganic layer. And in a case where the barrier and the convex-concave structure (for example, the protrusion) are materials having a certain elasticity, the stress in the inorganic layer can be uniformly and advantageously released, thereby further blocking an extension of the crack in the inorganic layer; furthermore, a contact area between the inorganic layer and the barrier is increased such that the bonding force between the barrier and the inorganic layer is increased.

For the present disclosure, the following points should be noted:

(1) The accompanying drawings in the embodiments of the present disclosure only involve structures relevant to the embodiments of the present disclosure, and other structures may refer to the conventional design.

(2) For clarity, in the accompanying drawings of the embodiments of the present disclosure, the thickness of layers or regions is enlarged or reduced. That is, the accompanying drawings are not drawn according to actual scales.

(3) The embodiments of the present disclosure and the characteristics in the embodiments may be mutually combined without conflict.

The described above are only specific embodiments of the present disclosure, and the present disclosure is not limited thereto. The scope of the present disclosure is defined by the accompanying claims.

What is claimed is:

1. A display substrate, comprising:
a base substrate, comprising a display region and a non-display region located around the display region;
an inorganic layer, located on the base substrate; and
at least one convex-concave structure, located in the non-display region and between the base substrate and the inorganic layer,
wherein an orthographic projection of the at least one convex-concave structure on the base substrate is within an orthographic projection of the inorganic layer on the base substrate.

2. The display substrate according to claim 1, further comprising a barrier, wherein the barrier is located in the non-display region and on a side of the inorganic layer away from the base substrate.

3. The display substrate according to claim 2, wherein the orthographic projection of the at least one convex-concave structure on the base substrate is within an orthographic projection of the barrier on the base substrate.

4. The display substrate according to claim 1, wherein the base substrate comprises an organic material, and
the at least one convex-concave structure is a protrusion contacting the base substrate.

5. The display substrate according to claim 4, wherein the protrusion is integrally formed with the base substrate.

6. The display substrate according to claim 1, wherein the base substrate comprises an organic material, and
the at least one convex-concave structure is a recess, and a portion of the base substrate facing the inorganic layer is configured to be the recess.

7. The display substrate according to claim 1, wherein the orthographic projection of the convex-concave structure on the base substrate is a closed loop and surrounds the display region.

8. The display substrate according to claim 7, wherein the at least one convex-concave structure comprises a plurality of convex-concave structures spaced from each other from inside to outside of the display region.

9. The display substrate according to claim 1, wherein a cross section of the at least one convex-concave structure in a direction perpendicular to an extension direction of the at least one convex-concave structure is at least one of an arc, a sector, a rectangle and a trapezoid.

10. The display substrate according to claim 2, further comprising:
an inorganic encapsulation layer, located on a side of the barrier away from the base substrate,
wherein an orthographic projection of the barrier on the base substrate is within an orthographic projection of the inorganic encapsulation layer on the base substrate.

11. The display substrate according to claim 2, further comprising:
a pixel defining layer, located in the display region,
wherein at least a portion of the barrier and the pixel defining layer are formed in a same layer by using a same material.

12. The display substrate according to claim 1, wherein the inorganic layer comprises at least one of a buffer layer, a gate insulating layer, an interlayer dielectric layer and a passivation layer.

13. The display substrate according to claim 1, further comprising:
a transition layer, located between the inorganic layer and the at least one convex-concave structure,
wherein the transition layer comprises an inorganic material, and the orthographic projection of the at least one convex-concave structure on the base substrate is located within an orthographic projection of the transition layer on the base substrate.

14. The display substrate according to claim 13, wherein the base substrate comprises a first material layer and a second material layer laminated with the first material layer, the second material layer is located between the first material layer and the transition layer,
the first material layer is an organic material layer, and the second material layer comprises an inorganic material and an organic material.

15. The display substrate according to claim 14, wherein the transition layer comprises an organic material, a content of the inorganic material is greater than a content of the organic material in the transition layer, and
a content of the organic material is greater than a content of the inorganic material in the second material layer.

16. A display device, comprising the display substrate according to claim 1.

17. A manufacturing method of a display substrate, comprising:
providing a base substrate, the base substrate comprising a display region and a non-display region located around the display region;
forming at least one convex-concave structure on the base substrate, the at least one convex-concave structure being in the non-display region; and
forming an inorganic layer on the base substrate on which the at least one convex-concave structure is formed,
wherein an orthographic projection of the at least one convex-concave structure on the base substrate is within an orthographic projection of the inorganic layer on the base substrate.

18. The manufacturing method according to claim 17, further comprising:
forming a barrier on the inorganic layer, the barrier being in the non-display region.

19. The manufacturing method according to claim 18, wherein
the orthographic projection of the at least one convex-concave structure on the base substrate is within an orthographic projection of the barrier on the base substrate.

20. The manufacturing method according to claim 17, wherein the forming the at least one convex-concave structure comprises:
patterning a surface of the base substrate, so that a portion of the surface of the base substrate facing the inorganic layer is formed to be the at least one convex-concave structure.
